(19) United States
(12) Patent Application Publication
(10) Pub. No.: US 2010/0068122 A1
(43) Pub. Date: Mar. 18, 2010

(54) Gem Growth Cubic Press and Associated Methods

(76) Inventor: Chien-Min Sung, Tansui (TW)

Correspondence Address: THORPE NORTH & WESTERN, LLP., P.O. Box 1219, SANDY, UT, 84091-1219, US

(21) Appl. No.: 12/541,064

(22) Filed: Aug. 13, 2009

Related U.S. Application Data
(60) Provisional application No. 61/091,600, filed on Aug. 25, 2008.

(51) Int. Cl. C01B 31/06; C30B 17/00; B01J 3/06

(52) U.S. Cl. 423/446; 117/223; 117/81

(57) ABSTRACT

A multiple anvil press can be configured for gem-quality growth. The press can include a plurality of opposing anvils, where the anvils are configured for simultaneous movement within a tolerance of less than about 0.5 mm as measured at each anvil surface, and each anvil can be aligned to a common center of all the anvils where the alignment is tuned to a tolerance of less than about 0.1 mm during use. The press can also include a reaction volume formed by the enclosure of all anvils, where the reaction volume has a size configured to facilitate single crystal growth per cycle time.

### PRIORITY DATA

This application claims the benefit of U.S. Provisional Patent Application Ser. No. 61/091,600, filed on Aug. 25, 2008, which is incorporated herein by reference.

### FIELD OF THE INVENTION

The present invention relates generally to devices and methods for growing crystalline materials at high pressures and high temperatures. Accordingly, the present invention involves the fields of chemistry, metallurgy, materials science, physics, and high pressure technology.

### BACKGROUND OF THE INVENTION

Apparatuses for achieving high pressures have been known for over a half century. Typical ultrahigh pressure apparatuses include piston-cylinder presses, cubic presses, tetrahedral presses, belt presses, girdle presses, multi-anvil presses and the like. Several of these apparatuses are capable of achieving ultrahigh pressures from about 4 GPa to about 7 GPa.

High pressure apparatuses are commonly used to synthesize diamond and cubic boron nitride (cBN). Generally, source materials and other raw materials can be selected and assembled into a high pressure assembly which is then placed in the high pressure apparatus. Under high pressure, and typically high temperature, the raw materials combine to form the desired product. More specifically, graphite, non-diamond carbon or even diamond can be used as a source material in diamond synthesis, while hexagonal boron nitride (hBN) can be used in cBN synthesis. The raw material can then be mixed or contacted with a catalyst material. Diamond synthesis catalysts such as Fe, Ni, Co, and alloys thereof are commonly used. Alkalis, alkaline earth metals, or compounds of these materials can be used as the catalyst material in cBN synthesis. The raw material and catalyst material can then be placed in a high pressure apparatus wherein the pressure is raised to an ultrahigh pressure, e.g., 5.5 GPa. An electrical current can then be passed through either a graphite heating tube or raw material, i.e., graphite directly. This resistive heating of the catalyst material is sufficient to cause melting of the catalyst material, e.g., typically about 1300° C. for diamond synthesis and about 1500° C. for cBN synthesis. Under such conditions, the raw material can dissolve into the catalyst and then precipitate dissolve into the catalyst and then precipitate out in a crystalline form as either diamond or cBN.

As technology has progressed, focus has been placed on growing larger numbers of crystals in a single cycle. The production of large numbers of crystals, and particularly diamonds, has been made possible by a number of innovative techniques and equipment advances, including crystalline seed placement, particular arrangement of catalyst and raw materials with respect to the number of seeds, more efficient equipment, etc. However, as the trend continues towards producing large quantities of diamonds, the quality remains of an industrial grade. The equipment configured for quantity growth, i.e. producing a large number of crystals, cannot sustain quality growth, especially gem-quality growth.

### SUMMARY OF THE INVENTION

Accordingly, the present invention provides a multiple anvil press that can be configured for gem-quality growth. The press can include a plurality of opposing anvils, where the anvils are configured for simultaneous movement within a tolerance of less than about 0.5 mm as measured at each anvil surface, and each anvil can be aligned to a common center of all the anvils were the alignment is tuned to a tolerance of less than about 0.1 mm during use. The press can also include a reaction volume formed by the enclosure of all anvils, where the reaction volume has a size configured to facilitate single crystal growth per cycle time.

Similarly, a method of forming gem-quality crystal is presented herein. The method includes forming a precursor body having a single crystalline seed contacting a catalyst material, where the catalyst material is in contact with a raw material. The method also includes pressing the precursor body by simultaneously advancing a plurality of anvils to form a pressurized reaction volume containing the precursor body. The reaction volume can have a size configured for efficient growth of a single crystal, and only a single crystal. The simultaneous advancement of the anvils can have a tolerance of less than about 0.5 mm of each anvil surface. Additionally, each anvil can be aligned to a common center of all the anvils to a tolerance of less than about 0.1 mm. The method can also include maintaining the pressurized volume for a sufficient amount of time, in some aspects, a week or more, to form one, and only one gem-quality crystal. Once the gem-quality crystal is formed, the pressurized volume can be depressurized and the crystal can be recovered.

In a specific embodiment, the gem-quality crystal created by the methods disclosed herein and/or with use of the press as described herein can be diamond or cubic boron nitride (cBN).

There has thus been outlined, rather broadly, the more important features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### DETAILED DESCRIPTION

Before the present invention is disclosed and described, it is to be understood that this invention is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting. It must be noted that, as used in this specification and the appended claims, the singular forms “a,” “an,” and “the” include plural referents unless the context clearly dictates otherwise. Thus, for example, reference to “a raw material” includes reference to one or more of such materials, and reference to “a high pressure apparatus” includes reference to one or more of such devices.

### Definitions

In describing and claiming the present invention, the following terminology will be used in accordance with the definitions set forth below.

As used herein, “anvil” refers to any solid mass capable of at least partially entering the die chamber sufficient to increase pressure within the reaction volume. Those skilled in the art will recognize various shapes and materials used for such anvils. Typically, the anvils have a frustoconical shape.

As used herein, “high pressure volume” and “reaction volume” can be used interchangeably and refer to at least a portion of the die chamber in which conditions can be maintained at a high pressure sufficient for useful testing and/or crystalline growth, e.g. usually the reaction volume can include a charge of raw material, i.e. nutrient source material, and catalyst materials for synthesis and growth of a gem-quality crystal. The reaction volume can be formed within a high pressure assembly placed at least partially within the die chamber.

As used herein, “high pressure” refers to pressures above about 1 MPa and preferably above about 200 MPa.

As used herein, “ultrahigh pressure” refers to pressures from about 1 GPa to about 15 GPa, and preferably from about 4 GPa to about 7 GPa.

As used herein, “alloy” refers to a solid solution or liquid mixture of a metal with a second material, said second material may be a non-metal, such as carbon, a metal, or an alloy which enhances or improves the properties of the metal.

As used herein, “seed” refers to a particle of either natural or synthetic diamond, super hard crystalline, or polycrystalline substance, or mixture of substances and include but are not limited to diamond, polycrystalline diamond (PCD), cubic boron nitride, SiC, and the like. Crystalline seeds can be used as a starting material for growing larger crystals and help to avoid random or unwanted nucleation and growth of crystal.

As used herein, “raw material” refers to materials used to form a crystal. Specifically, raw material is a source of material which provides a nutrient for growth of a crystal, e.g., carbon of various forms such as graphite, boron nitride of various forms such as hBN, etc.

As used herein, “superabrasive” refers to particles of diamond or cBN. As used herein, “precursor” and “precursor body” refers to an assembly of a crystalline seed, catalyst material, and a raw material. A precursor describes such an assembly prior to the crystalline or diamond growth process, i.e. a “green body.”

As used herein, “inclusion” refers to entrapment of non-crystalline (i.e. non-diamond or non-cBN) material within a growing crystal. Frequently, the inclusion is a catalyst metal enclosed within the crystal under rapid growth conditions. Alternatively, inclusions can be the result carbon or other raw material deposits forming instead of the desired crystal at the interface between a crystal growth surface of the crystal and the surrounding material. In general, inclusions are most often formed by the presence of substantial amounts of raw material at the growth surface of the diamond and/or inadequate control of temperature and pressure conditions during HPHT growth.

As used herein, “contacting” refers to physical intimate contact between two materials. For example, a crystalline seed can be placed “contacting” a catalyst layer. As such, the crystalline seed can be in contact with a surface of the catalyst layer, partially embedded therein, or fully embedded in the catalyst layer.

As used herein, “gem quality” refers to crystals that are of a color and clarity that is deemed acceptable for jewelry purposes. Several different scales for ranking the clarity and color characteristics of gem stones are known, for example the Diamond Quality Report used by the Gemological Institute of America (GIA). In some cases, such crystals may have no or substantially no visible irregularities (e.g., inclusions, defects, etc.) when observed by the unaided eye. Crystals grown in accordance with the present invention exhibit a comparable gem quality to that of natural crystals which are suitable for use in jewelry.

As used herein, “alignment” refers to the ability of all anvils to advance toward a common center of a high pressure cell. As used herein, “synchronization” refers to the timely positioning of each anvil. Meaning, noted anvils move, often relative to the common center of a high pressure cell, at the same time, and thus, are equidistant from the common center at any point in time. In general, a squeezed cube made of aluminum or pyrophillite is used to check alignment and synchronization. The offset of indentation marks on opposite sides indicates alignment. The difference of the depth of indentation on opposite sides provides the synchronization.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, a plurality of items, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

As used herein, the term “about” means that dimensions, amounts, formulations, parameters, and other quantities and characteristics are not and need not be exact, but may be approximated and/or larger or smaller, as desired, reflecting tolerances, conversion factors, rounding off, measurement error and the like and other factors known to those of skill. Further, unless otherwise stated, the term “about” shall expressly include “exactly,” consistent with the discussion above regarding ranges and numerical data.

Concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a numerical range of about 1 to about 4.5 should be interpreted to include not only the explicitly recited limits of 1 to about 4.5, but also to include individual numerals such as 2, 3, 4, and sub-ranges such as 1 to 3, 2 to 4, etc. The same principle applies to ranges reciting only one numerical value, such as “less than about 4.5,” which should be interpreted to include all of the above-recited values and ranges. Further, such an interpretation should apply regardless of the breadth of the range or the characteristic being described.

### Invention

Accordingly, the present disclosure is directed to a precision gem machine and method of forming gem-quality crystals. As noted, the trend in superabrasive manufacture is towards quantity formation and producing a greater number of abrasive particles in a single reaction process. The natural result of such pursuit is equipment having a larger reaction volume. In enlarging the reaction volume, the overall control of the contents of the reaction volume during processing is naturally diminished. The further advancement, then, tends towards obtaining greater control over the larger processing equipment. However, gem-type crystals may be desirable, and such cannot be effectively and efficiently grown in the equipment presently available on the market.

The inventor has discovered that substantially reducing the reaction volume to accommodate a single crystal growth, combined with HPHT growth instigated and sustained by an anvil press, allows for intricate control over the variables of crystal formation to an extent that gem-quality crystals, particularly diamond and/or cBN, can be formed consistently. Gem quality growth depends on precise control of pressure and temperature for extended periods of time, even days, or a week or more (i.e. 10-14 days) because significant time is required in order to allow the formation of a crystalline lattice that is sufficiently perfect to meet gem quality standards. To contrast, many of the present apparatuses and methods are geared towards growing as many as tens of thousands of industrial diamond crystals in short durations, such as 30 minutes. Growth in the current machinery and times cannot meet the necessary precision necessary for gem quality crystal growth. Furthermore, the intrinsic temperature gradients in radial and longitudinal directions within current machinery would preclude the growth of gem diamond crystals simultaneously.

The present method and apparatus, however, is configured for single crystal growth. The apparatus is a multiple anvil press that can be configured for gem-quality growth. The press can include a plurality of opposing anvils, where the anvils are configured for simultaneous movement within a tolerance of less than about 0.5 mm as measured at each anvil surface, and each anvil can be aligned to a common center of all the anvils where the alignment is tuned to a tolerance of less than about 0.1 mm during use. The press can also include a reaction volume formed by the enclosure of all anvils, where the reaction volume has a size configured to facilitate single crystal growth per cycle time.

Similarly, a method of forming gem-quality crystal is presented herein. The method includes forming a precursor body having a single crystalline seed contacting a catalyst material, where the catalyst material is in contact with a raw material. The method also includes pressing the precursor body by simultaneously advancing a plurality of anvils to form a pressurized reaction volume containing the precursor body. The reaction volume can have a size configured for efficient growth of a single crystal, and in most aspects, only a single crystal or stone. The simultaneous advancement of the anvils can have a tolerance of less than about 0.5 mm of each anvil surface. Additionally, each anvil can be aligned to a common center of all the anvils to a tolerance of less than about 0.1 mm. The method can also include maintaining the pressurized volume to form one gem-quality crystal or stone, and in most aspects, only one gem-quality crystal or stone. Once the gem-quality crystal is gem-quality crystal is formed, the pressurized volume can be depressurized and the crystal can be recovered.

In a specific embodiment, the gem-quality crystal created by the methods disclosed herein and/or with use of the press as described herein can be diamond or cubic boron nitride (cBN).

A precursor body can be configured for placement in the reaction volume. The precursor body can typically include materials for growing a crystalline body from a crystalline seed. In one aspect, materials suitable for a precursor body can include one crystalline seed, a catalyst layer, and a raw material layer. In one aspect, the materials can be configured for temperature gradient controlled crystal growth. In some aspects, the materials are selected and provided in an amount that is suitable only for growing a single gem-quality crystal or stone. As such, the crystalline seed can be separated from the raw material layer by the catalyst layer to form a precursor body.

The catalyst layer can be formed of nearly any suitable catalyst material, depending on the desired grown crystal. Catalyst materials suitable for diamond synthesis can include metal catalyst powder or solid layers comprising any metal or alloy, which includes a carbon solvent capable of promoting growth of diamond from carbon source materials. Non-limiting examples of suitable metal catalyst materials can include Fe, Ni, Co, Mn, Cr, and alloys thereof. Several common metal catalyst alloys can include Fe—Ni, e.g., INVAR alloys, Fe—Co, Ni—Mn—Co, and the like. Currently preferred metal catalyst materials are Fe—Ni alloys, such as Fe—35Ni, Fe—31Ni—5Co, Fe—50Ni, and other INVAR alloys, with Fe—35Ni being the most preferred and readily available. Additionally, a catalyst material can include multiple materials in mixtures and/or layers.

Similarly, catalyst materials suitable for cBN synthesis can include any catalyst capable of promoting growth of cBN from suitable boron nitride raw materials. Non-limiting examples of suitable catalyst materials for cBN growth include alkali metals, alkaline earth metals, and compounds thereof. Several specific examples of such catalyst materials can include lithium, calcium, magnesium, nitrides of alkali and alkaline earth metals such as Li₃N, Ca₃N₂, Mg₃N₂, CaBN₂, and Li₃BN₂. The catalyst materials under cBN synthesis can further include very minor amounts of additives, which control the growth rate or interior color of the cBN crystal such as Si, Mo, Zr, Ti, Al, Pt, Pb, Sn, B, C, and compounds of these materials with Si, B, and N.

The amount and dimensions of the components of the precursor body can be selected based on the desired end-product gem-quality crystal. Preferably, the raw material is not the limiting factor in crystal growth. As such, in one aspect, the raw material can be at least about four times the final size of the produced gem quality crystal. In another embodiment, the precursor body can have a volume of greater than about ten times the volume of the produced gem quality crystal. In either case, the amount of raw material provided can be specifically preselected in quantity to be an amount sufficient to only grow a single gem-quality crystal or stone of the selected size, (i.e. 1 ct., 2 ct., 5 ct., etc.).

The catalyst material can be formed into any suitable dimension that allows for diffusion of raw materials into the catalyst layer and maintenance of a temperature gradient extending over the time of the crystal growth. Typically, the catalyst layer can be from about 1 mm to about 20 mm in thickness. However, thicknesses outside this range can be used depending on the desired growth rate, magnitude of temperature gradient, and the like. Again, in some aspects, the amount of catalyst material can be specifically preselected in quantity to be an amount sufficient to only grow a single gem-quality crystal or stone of the selected size, such as 0.5, 1, 2, or 5 ct., etc.

In the precursor, and once the precursor is in the reaction chamber, one crystalline seed, and in most aspects, only one crystalline seed, can contact the catalyst material. A crystalline seed can be placed in a position contacting the catalyst material, or can be placed partially or wholly within the catalyst material. The crystalline seed can be any suitable seed material upon which growth can occur for gem quality crystal. In a specific embodiment, the gem quality crystal can be either diamond or cBN. In another aspect of the present invention, the crystalline seed can be diamond seeds, cBN seeds, or SiC seeds. The synthesis of either diamond or cBN can utilize any of the listed crystalline seeds that have similar crystal structures. Frequently, diamonds seeds are the preferred crystalline seeds for diamond synthesis, although cBN or SiC seeds can also be used. Similarly, in some embodiments of cBN synthesis, cBN seeds can be used, although diamond or SiC seeds can also be used.

Typically, the crystalline seed can have a diameter of from about 30 μm to about 1 mm, and preferably from about 50 μm to about 500 μm. However, the presently disclosed method and apparatus can be used in growth of almost any size crystalline seed. Utilizing larger seeds generally reduces the required time for forming a larger gem quality crystal.

In one alternative embodiment, the crystalline seed and catalyst material can be separated by a partition layer. Under some circumstances, especially during early stages of crystal synthesis, a nutrient deficient molten catalyst layer may completely dissolve the crystalline seed before the catalyst layer is sufficiently saturated with nutrient, i.e. raw material, to begin growth of the crystal. In order to reduce or prevent excessive dissolution of the crystalline seed, particularly for small seeds, a thin partition layer can be placed between the crystalline seed and the catalyst material. For example, the partition layer can be in the form of a coating around the crystalline seed or may be a layer along the growth surface which provides a temporary barrier to catalyst material. The partition layer can be formed of any material, metal, or alloy having a melting point higher than the melting point of the catalyst material. One exemplary partition layer material includes platinum. Thus, the partition layer can preserve the crystalline seed until the catalyst layer is saturated (or substantially saturated) with nutrient material. The partition layer can be adjusted in thickness and composition to allow the partition layer to be substantially removed, i.e. dissolved or otherwise rendered a non-barrier, such that growth of the crystalline seed can occur once sufficient nutrient material is dissolved in the catalyst layer. In a specific embodiment, the platinum partition can have a breach or hole that exposes the crystalline seed. In a further embodiment, the breach of the partition can be strategically placed on the crystalline seed so as to expose a desired growth face. For example, a platinum partition can have a hole where the (100) face of a diamond seed is exposed. Such an arrangement can reduce or prevent spontaneous nucleation of extra diamond crystal.

The raw material can be configured to provide a source of raw material for growth of a desired crystalline body such as diamond or cBN from a crystalline seed. Specifically, a carbon source can be used as the raw material for diamond growth, while a low pressure phase boron nitride such as hBN (white graphite) or pyrolitic boron nitride (pBN) can be used as the raw material for cBN growth. Under diamond growth conditions, the carbon source layer can comprise a carbon source material such as graphite, amorphous carbon, diamond powder, and the like. In one aspect of the present invention, the carbon source layer can comprise high purity graphite. Although a variety of carbon source materials can be used, graphite generally provides good crystal growth and improves homogeneity of the grown diamond. Further, low resistivity graphite also provides a carbon source material which can also be readily converted to diamond.

The raw material can be configured, based on proximity to and arrangement with respect to the crystalline seed and the catalyst material, to allow raw material to diffuse into the catalyst layer along a bulk raw material diffusion direction. The bulk raw material diffusion direction can be oriented substantially parallel to, perpendicular to, or at an angle to gravity during application of high pressure. As a single crystal is grown per cycle, the arrangement that is preferable is perpendicular to gravity.

A multiple anvil press can be utilized to press the precursor body to form a single gem quality crystal. As noted previously, the multiple anvil press can include a plurality of opposing anvils, each aligned to a common center. The number of anvils can vary depending on the particular application, however, in one aspect, the press can have six anvils. The anvils can be configured for simultaneous movement within a tight tolerance of less than about 0.5 mm as measured at each anvil surface. Further, the moving forces controlling more than one anvil can be configured, so as to result from a single force. Typically, multiple anvil forces can be controlled by distinct forces, unconnected to other anvil movement. Such design is difficult to synchronize to the required tolerance herein, as hydraulic fluid and other movement means for each anvil must be appropriately tuned, even between pressing cycles. On the contrary, more than one anvil can be driven by a single ram, thus inherently synchronizing the movement. In a further aspect, a single ram can be utilized to drive the majority of or all of the anvils of the press.

Alternatively, or in conjunction with the single ram, a common displacement block or anvil block can be utilized to synchronize the movement of anvils. A single block can be used to physically advance multiple anvils. To facilitate the movement, while maintaining the anvils desired alignment, the block can be configured to allow for controlled sliding by the anvil against the block. As such, the displacement block can be angled or rounded appropriately to allow for the each contacting anvil to maintain the desired alignment towards the common center of the anvils. In one aspect, one anvil can be aligned to move in the direction of the direct force of the displacement block. In one embodiment, the displacement block can be directly and permanently attached to an anvil. Anvils note permanently connected to the displacement block can be in contact along a surface of the block and function by sliding in the desired direction. In a specific embodiment, a single ram can be utilized to drive six anvils. The driving mechanism can convert vertical movement of a press platen to synchronize movement of all anvils. A sloped (e.g. 45 degree) block can be utilized to slide four anvils set up on a horizontal layout, while the bottom anvil is compressed by the block toward the top anvil, thus all six anvils are simultaneously moving towards a common center. Another configuration is to mount three anvils on the inside of a cube corner and thrust it against another three anvils placed in an opposite another three anvils placed in an opposite corner of the imaginary cube. Such advancement is again affected by sliding backing plates.

The sliding, when utilizing a block can be aided by the application of a lubricant along the sliding surface. Most importantly, the friction between the sliding surfaces affected by a single block will be calculated so as to maintain the desired synchronization and alignment. Lubricants are known in the art, but can include, for example polytetrafluoroethylene (Teflon ®). Other modifications to the apparatus can enhance the alignment and synchronization. Guiding pins, if formed to a tight tolerance, can assist in the alignment of the anvils. Incorporating transducers for controlling at least one or even all anvil movement can be effectively utilized to improve the synchronization to the desired tolerance.

Typically, the alignment of the anvils is towards the common center of all of the anvils. The alignment and/or synchronization can be measured, for example, by pressing a block of, for example, aluminum or pyrophillite. The indentation marks are examined for each anvil face. Synchronization is reflected by the depth of the indentations, and should be less than about 0.5 mm difference among all anvils. The alignment of the anvils is reflected by the indentation offsets, and should be less than 0.1 mm from the opposing anvil.

In accordance with the present invention, a high pressure multiple anvil press can include a plurality of anvils. The anvils of the present invention can be assembled to form a reaction volume. The reaction volume can be at least partially filled with a precursor body containing materials to be subjected to high pressures. Each anvil can be aligned with an opposing complementary anvil. All anvils can then be moved towards each other, and simultaneously towards a common center, to compress the precursor body and apply force thereto. In one aspect, retention measures and devices can be incorporated into the method and apparatus to better retain the anvils in the pressing state, thus allowing an extended time for the desired crystal growth.

The inner surfaces of the plurality of anvils can be configured to form a reaction volume having a predetermined cross-section. Specifically, the inner surfaces can be, but are not limited to, arcuate, flat, or contoured surfaces. For example, when assembled, arcuate inner surfaces can form a reaction volume having a circular cross-section. Similarly, when assembled, flat inner surfaces can form a reaction volume having triangle, square, pentagon, and the like cross-sections, depending on the number of die segments.

In accordance with the present invention, the number of complementary anvils can vary from two to any practical number. In one aspect, the multiple anvil press apparatus of the present invention can include from two to ten complementary anvils. As the number of anvils increases, the relative size of each anvil face decreases. A larger number of anvils can increase complexity and maintenance costs of the apparatus, and more importantly, can lead to a configuration wherein the desired alignment and synchronization cannot be met. The anvils, and the anvil press generally, can be formed of any hard material having a high compressive strength. Examples of suitable hard material for forming anvils of the present invention can include, but are not limited to, cemented tungsten carbide, alumina, silicon nitride, zirconium dioxide, hardened steel, super alloys, i.e. cobalt, nickel and iron-based alloys, and the like. In a preferred embodiment, the anvils can be formed of cemented tungsten carbide. Preferred cemented tungsten carbides can be formed of submicron tungsten carbide particles and include a cobalt content of about 6 wt %. Those of ordinary skill in the art will recognize other materials that may be particularly suited to such high pressure devices.

The reaction volume can include the precursor body, and optionally metal braze coatings, gasket materials, graphite heating tubes, resistors, and the like. Those skilled in the art will recognize additional items and materials that can be of benefit to include in the reaction volume.

In accordance with the present invention, the force members can be any device or mechanism capable of applying force sufficient to advance and/or retain the anvils in a pressing, and reasonably static, position for an amount of time required to grow a single gem quality diamond of specifically selected size. Several non-limiting examples of suitable force members include uniaxial presses, hydraulic pistons, and the like. Hydraulic pistons and rams similar to those used in tetrahedral and cubic presses can also be used in the high pressure apparatus of the present invention. Alternatively, the force members can include tie rods and hydraulic pistons similar to those used in a standard cubic press. It should be noted that the force of the force members can be applied to one or more displacement blocks, as noted previously.

In accordance with the above principles, the apparatus of the present invention can produce high pressures within the reaction volume. High pressures of over about 2 MPa can be easily achieved. In one aspect, the combined pressing forces are sufficient to provide ultrahigh pressures. In one detailed aspect, the ultrahigh pressures can be from about 1 GPa to about 10 GPa, and preferably from about 2 GPa to about 7 GPa, and most preferably from about 4 to about 6 GPa. The pressing force can be maintained for the time required to achieve the desired amount of gem quality crystal growth. As previously noted, gem quality growth requires extended periods of time compared to industrial quality crystal growth. As such, the multiple anvil press presently disclosed can be configured to maintain the pressing force for greater than about 24 hours, or even for greater than about 2 days or more. In some aspects, the time required may be about 3 days, about 4 days, about 5 days, or about a week. During such time, it is desirable to have the pressure gradient and other conditions in the growth chamber remain nearly completely static. In some aspects, each parameter of the conditions changes by less than about 10%. In another aspect, the parameters chance by less than 5%. In yet other aspects, the parameters and other conditions change by less than 1% for the duration of the growth operation.

Typical growth conditions can vary somewhat; however, the temperature can be from about 1000° C. to about 1600° C. and the pressure can be from about 2 to about 7 GPa, and preferably from about 4 to about 6 GPa. The appropriate temperature can depend on the catalyst material chosen as well as the desired crystal. As a general guideline, the temperature can be from about 10° C. to about 200° C. above a melting point of the catalyst.

The apparatuses and methods presently disclosed can provide additional control and improved quality of each individually grown crystal. As is known, the arrangement of the materials in the precursor body can be configured to encourage growth in a particular direction and/or along a particular growth face. During synthesis of diamond, the catalyst is substantially molten such that lower density diamond (3.5 g/cm³) tends to float on the more dense molten catalyst (density greater than 8 g/cm³). Moreover, the molten catalyst may flow upward via convection, if the lower portion of the molten catalyst is at a higher temperature than an upper portion. Such flow of molten catalyst or diamond is not desirable, e.g., under the temperature gradient method of diamond synthesis, convection can increase diffusion of carbon solute sufficient to disturb the growth rate of the seeded diamond resulting in non-homogeneous crystal formation and defects. Thus, one aspect of the present invention can include orienting the seed, raw material, and catalyst material, so as to substantially eliminate or substantially reduce such unwanted effects.

In addition, in accordance with the present invention, temperature profiles within the reaction volume can be actively controlled in order to maintain optimal growth conditions for the crystal growth. Typically, in accordance with the temperature gradient method, each growth surface and/or crystalline seed can have a lower temperature than a corresponding raw material flux surface. Typically, the temperature profile within the reaction volume can be a negative gradient from the raw material to the crystalline seed. The temperature difference can vary, but is typically from about 20° C. to about 50° C. Further, temperature fluctuations at the crystalline seed below about 10° C. are desirable in order to avoid defects or inclusions in a growing crystal.

A variety of mechanisms can be used in order to maintain a desired temperature profile within the reaction volume. Heating elements can be provided in thermal contact with the raw material. Suitable heating elements can include, but are not limited to, passing a current through low resistivity raw material, heating tubes, and the like. Similarly, the crystalline seed and growth surface can be cooled by thermal contact with cooling elements. Suitable cooling elements can include, but are not limited to, cooling tubes, refrigerants, and the like. Cooling elements can be placed adjacent existing pressure members or can be formed as an integral part of pressure members or reaction assemblies. As an additional aid to actively controlling temperature profiles, thermocouples can be used to measure temperature profile. Thermocouples can be placed at various locations within the reaction volume to determine whether temperatures are being maintained within optimal growth conditions.

The heating and cooling elements can then be adjusted to provide adequate heating or cooling. Typical feedback schemes can be used to reduce fluctuations in temperature control, i.e. PID, PI, etc.

The multiple anvil press, as is known in the art, can include a number of other parts and connections to allow for correct operation. The present disclosure does not detail what is known in the art of multiple anvil presses, rather explains modifications to and improvements on the apparatus and method of use to provide a means of consistently forming one single gem quality crystal per cycle. The reaction volume is significantly smaller than what is typically used in industry. The general size of the necessary reaction volume is dependent upon the desired size of the resulting grown crystal. The size is preferably large enough so as to allow for adequate growth materials (i.e. catalyst and raw material) so that the materials are not limiting factors to the growth. In one specific aspect, the reaction volume can be less than about 10 cm²; in another aspect, the reaction volume can be less than about 1 cm², or even less than about 0.1 cm².

In one aspect, a multiple anvil press can have a single growth volume. The growth volume can have a single temperature gradient throughout the growth volume during growth. Specifically, the growth volume can have said temperature gradient from a raw material to a single crystalline seed. In this manner, the system is most efficient and reduces the likelihood of un-seeded growth. A single gem-quality crystal can be grown in a relatively tight space, with a uniform, or substantially uniform, pressure field and small to minimal temperature variation. In some aspects, the pressure and temperature conditions within the reaction chamber, including pressure and temperature gradients may be static, or substantially static, throughout the entire growth process for a sufficient amount of time to grow the desired gem-quality crystal. Such static conditions allow little, if any, changes over time in order to maximize the gem-quality of the single crystal produced. It should be noted that the growth typically occurs by the temperature gradient method, however the temperature variation in the growth cell apart from the temperature gradient is the temperature variation within the growth cell. For example, the temperature variation can be the variation of temperature of the raw material. Generally, temperature variation is undesirable. In one aspect, the temperature gradient growth method may not be relied on, in which case, it may be desirable to have no to minimal temperature variation (gradient or otherwise) throughout the growth volume. It may further be desirable to keep such temperature, with or without variation in the cell static or substantially static over time, optionally along with the pressure conditions, including any pressure gradient.

Generally, conventional presses utilizing multiple anvils cannot be aligned and synchronized to the noted tolerances.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A multiple anvil press configured for gem-quality crystal growth, comprising:
a plurality of opposing anvils, said anvils configured for simultaneous movement within a tolerance of less than about 0.5 mm as measured at each anvil surface, wherein each anvil is
aligned to a common center of all anvils to a tolerance of less than about 0.1 mm during use; and
a reaction volume formed by the enclosure of all anvils, said reaction volume having a size configured to accommodate growth of only a single crystal per cycle time.

2. The press of claim 1, wherein the press has six anvils.

3. The press of claim 1, at least half of the anvils are driven by a single ram.

4. The press of claim 3, wherein all anvils are driven by a single ram.

5. The press of claim 3, wherein more than one anvil advancement is facilitated by sliding backing plates of the anvils against a common displacement block.

6. The press of claim 5, wherein polytetrafluoroethylene is utilized as a lubricant.

7. The press of claim 1, wherein the press is configured to maintain gem-quality growth heat and temperature conditions for greater than about 24 hours.

8. The press of claim 1, wherein the reaction volume has a volume of greater than about 10 times the volume of a desired crystal.

9. The press of claim 1, wherein the advancement of the anvils is transducer-controlled.

10. A method of forming a single gem-quality crystal, comprising:
forming a precursor body having a single crystalline seed contacting a catalyst material, said catalyst material in contact with a raw material;
pressing the precursor body by simultaneously advancing a plurality of anvils to form a pressurized reaction volume containing the precursor body, said reaction volume having a size configured for efficient growth of only a single crystal, said simultaneously advancing of the anvils having a tolerance of less than about 0.5 mm of each anvil surface, wherein each anvil is
aligned to a common center of all the anvils to a tolerance of less than about 0.1 mm;
maintaining the pressurized volume at substantially static temperature and pressure gradient conditions for a period of time sufficient to form one gem-quality crystal;
depressurizing the pressurized volume; and
recovering the gem-quality crystal.

11. The method of claim 10, wherein six anvils are simultaneously advanced.

12. The method of claim 10, wherein the step of maintaining the pressurized volume lasts greater than 24 hours.

13. The method of claim 10, wherein the crystalline seed is diamond.

14. The method of claim 10, wherein the raw material is graphite.

15. The method of claim 10, wherein the crystalline seed is cBN.

16. The method of claim 10, wherein the temperature and pressure gradient conditions degrade by less than 10% of the originally established gradient conditions.

17. The method of claim 10, wherein the advancement of the anvils is controlled by a transducer.

18. The method of claim 10, wherein the precursor body has a volume of greater than about 10 times of a volume of the gem-quality crystal.

19. The method of claim 10, wherein the raw material of the precursor body has a volume of greater than about 4 times a volume of the gem-quality crystal.

20. A gem-quality crystal created by the method of claim 10.
